(19) United States
(12) Patent Application Publication
(10) Pub. No.: US 2018/0005867 A1
(43) Pub. Date: Jan. 4, 2018

(54) ESC CERAMIC SIDEWALL MODIFICATION FOR PARTICLE AND METALS PERFORMANCE ENHANCEMENTS

(71) Applicant: LAM RESEARCH CORPORATION, Fremont, CA (US)

(72) Inventor: Eric A. Pape, Campbell, CA (US)

(21) Appl. No.: 15/594,091

(22) Filed: May 12, 2017

Related U.S. Application Data
(60) Provisional application No. 62/357,513, filed on Jul. 1, 2016.

(51) Int. Cl. H01L 21/687; C04B 41/87; C23C 28/04; C04B 37/00; C04B 41/00; C04B 41/50

(52) U.S. Cl. CPC H01L 21/68757; C04B 41/009; C04B 41/5045; C23C 28/042; H01L 21/68785; C04B 37/008; H01L 21/68735; C04B 41/87; C04B 2237/02; C04B 2237/366; C04B 2237/343

(57) ABSTRACT

A substrate support for a substrate processing system includes a baseplate and a ceramic layer arranged on the baseplate. The ceramic layer includes a lower surface, an upper surface configured to support a substrate, and sidewalls around a perimeter of the ceramic layer extending from the lower surface to the upper surface, and the ceramic layer comprises a first material. A bond layer is provided between the baseplate and the ceramic layer. A protective layer is formed on the sidewalls of the ceramic layer. The protective later comprises a second material different from the first material.

### CROSS-REFERENCE TO RELATED APPLICATIONS

This application claims the benefit of U.S. Provisional Application No. 62/357,513, filed on Jul. 1, 2016. The entire disclosure of the application referenced above is incorporated herein by reference.

### FIELD

The present disclosure relates to substrate processing systems, and more particularly to systems and methods for protecting sidewalls of a ceramic layer of a substrate support.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Example processes that may be performed on a substrate include, but are not limited to, chemical vapor deposition (CVD), atomic layer deposition (ALD), conductor etch, and/or other etch, deposition, or cleaning processes. A substrate may be arranged on a substrate support, such as a pedestal, an electrostatic chuck (ESC), etc. in a processing chamber of the substrate processing system. During etching, gas mixtures including one or more precursors may be introduced into the processing chamber and plasma may be used to initiate chemical reactions.

A substrate support such as an ESC may include a ceramic layer arranged to support a wafer. For example, the wafer may be clamped to the ceramic layer during processing. The ceramic layer may be bonded to a baseplate of the substrate support using a bonding layer, which may comprise materials including, but not limited to, silicone with a filler, an epoxy matrix material, etc. The baseplate may comprise a cooled aluminum baseplate.

### SUMMARY

A substrate support for a substrate processing system includes a baseplate and a ceramic layer arranged on the baseplate. The ceramic layer includes a lower surface, an upper surface configured to support a substrate, and sidewalls around a perimeter of the ceramic layer extending from the lower surface to the upper surface, and the ceramic layer comprises a first material. A bond layer is provided between the baseplate and the ceramic layer. A protective layer is formed on the sidewalls of the ceramic layer. The protective later comprises a second material different from the first material.

In other features, the second material is a non-alumina based material. The second material is an yttrium oxide spraycoat. The second material has a greater resistance to plasma than the first material. A thickness of the protective layer is between 0.005″ and 0.010″.

In other features, the protective layer extends from a bottom edge of the sidewalls adjacent to the lower surface to a top edge of the sidewalls adjacent to the upper surface. The protective layer extends from a bottom edge of the sidewalls adjacent to the lower surface to a predetermined distance from a top edge of the sidewalls adjacent to the upper surface. The predetermined distance is at least 0.001″ from the top edge.

In still other features, a top edge of the sidewalls adjacent to the upper surface is chamfered. A thickness of the protective layer tapers at at least one of a bottom edge of the sidewalls adjacent to the lower surface and a top edge of the sidewalls adjacent to the upper surface. The thickness of the protective layer tapers from between 0.005″ and 0.010″ to 0.001″. A protective seal is arranged around a perimeter of the bond layer between the baseplate and the lower surface of the ceramic layer and the protective seal does not extend onto the lower surface of the ceramic layer.

A method for forming a substrate support for a substrate processing system includes providing a baseplate, depositing a bond layer on the baseplate, and arranging a ceramic layer on the baseplate. The ceramic layer includes a lower surface, an upper surface configured to support a substrate, and sidewalls around a perimeter of the ceramic layer extending from the lower surface to the upper surface, and the ceramic layer comprises a first material. The method further includes at least one of forming a protective layer on the sidewalls of the ceramic layer, the protective later comprising a second material different from the first material, polishing the sidewalls of the ceramic layer, and acid-etching the sidewalls of the ceramic layer.

In other features, the second material is a non-alumina based material. Forming the protective layer includes applying an yttrium oxide spraycoat on the sidewalls of the ceramic layer. The second material has a greater resistance to plasma than the first material.

In other features, polishing the sidewalls of the ceramic layer includes polishing the sidewalls to a surface roughness of less than 30 micro-inches. Polishing the sidewalls of the ceramic layer includes polishing the sidewalls to a surface roughness of less than 10 micro-inches.

In still other features, acid-etching the sidewalls of the ceramic layer includes acid-etching the sidewalls to remove an outer portion of a glassy phase material of the sidewalls.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example substrate processing system including a substrate support according to the principles of the present disclosure;

FIG. 2A is an example substrate support including a protective layer according to the principles of the present disclosure;

FIG. 2B is another example substrate support including a protective layer according to the principles of the present disclosure;

FIG. 2C is another example substrate support including a protective layer according to the principles of the present disclosure;

FIG. 3 illustrates steps of a first example method of forming a substrate support according to the principles of the present disclosure;

FIG. 4 illustrates steps of a second example method of forming a substrate support according to the principles of the present disclosure; and

FIG. 5 illustrates steps of a third example method of forming a substrate support according to the principles of the present disclosure.

In the drawings, reference numbers may be reused to identify similar and/or identical elements.

### DETAILED DESCRIPTION

A substrate support such as an electrostatic chuck (ESC) in a processing chamber of a substrate processing system may include a ceramic layer bonded to a conductive baseplate. For example only, the ceramic layer may comprise a first, primary material (e.g., aluminum oxide grains, aluminum nitride, etc.) with metal oxide binders. In other examples, metal oxide binders may be omitted. Purity of the primary material may be 90% or greater.

The ceramic layer may be exposed to plasma, including radicals, ions, reactive species, etc., within the chamber at an outer edge of the substrate support. Exposure to the plasma may cause portions of the ceramic layer to erode (i.e., wear) overtime due to process mechanisms including, but not limited to, fluoridation, ion bombardment, etc. Such wear may allow materials of the ceramic layer to migrate into a reaction volume of the processing chamber, which may adversely affect substrate processing. For example, direct molecular and/or particle material removed from the ceramic layer may be suspended within plasma, and may be deposited on the edge ring or other process chamber hardware. This material can then be redeposited on the surface of the substrate during subsequent processing. In other words, wear of the ceramic layer due to exposure to plasma may cause particle generation and contamination of the process chamber, resulting in substrate defects.

Systems and methods according to the principles of the present disclosure implement one or more modifications of a sidewall of the ceramic layer to reduce contamination and particle generation caused by exposure of the material of the ceramic layer to plasma. In one example, sidewalls of the ceramic layer are coated with a protective layer or coating. The protective layer may include a non-alumina based material, such as an yttrium oxide spraycoat. The protective layer provides a barrier between reactive species within the processing chamber and the ceramic layer. In another example, the sidewalls of the ceramic layer are polished. Polishing reduces the surface area of the sidewalls, thereby reducing the amount of material exposed to plasma. In still another example, the sidewalls of the ceramic layer are acid-etched. Acid-etching the sidewalls preemptively and preferentially removes material from the ceramic layer that would otherwise be removed during other plasma processes and resulting impurities within the chamber.

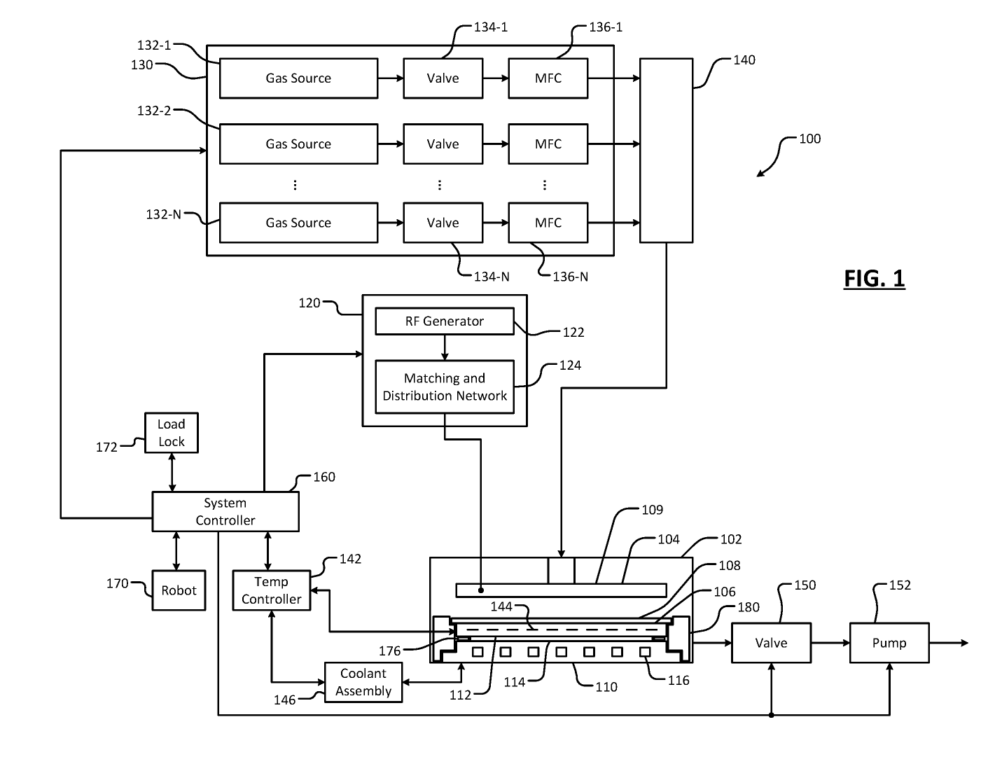

Referring now to FIG. 1, an example substrate processing system 100 is shown. For example only, the substrate processing system 100 may be used for performing etching using RF plasma and/or other suitable substrate processing. The substrate processing system 100 includes a processing chamber 102 that encloses other components of the substrate processing system 100 and contains the RF plasma. The substrate processing chamber 102 includes an upper electrode 104 and a substrate support 106, such as an electrostatic chuck (ESC). During operation, a substrate 108 is arranged on the substrate support 106. While a specific substrate processing system 100 and chamber 102 are shown as an example, the principles of the present disclosure may be applied to other types of substrate processing systems and chambers, such a substrate processing system that generates plasma in-situ, that implements remote plasma generation and delivery (e.g., using a microwave tube), etc.

For example only, the upper electrode 104 may include a showerhead 109 that introduces and distributes process gases. The showerhead 109 may include a stem portion including one end connected to a top surface of the processing chamber. A base portion is generally cylindrical and extends radially outwardly from an opposite end of the stem portion at a location that is spaced from the top surface of the processing chamber. A substrate-facing surface or faceplate of the base portion of the showerhead includes a plurality of holes through which process gas or purge gas flows. Alternately, the upper electrode 104 may include a conducting plate and the process gases may be introduced in another manner.

The substrate support 106 includes a conductive baseplate 110 that acts as a lower electrode. The baseplate 110 supports a ceramic layer 112. In some examples, the ceramic layer 112 may comprise a heating layer, such as a ceramic multi-zone heating plate. A thermal resistance layer 114 (e.g., a bond layer) may be arranged between the ceramic layer 112 and the baseplate 110. The baseplate 110 may include one or more coolant channels 116 for flowing coolant through the baseplate 110.

An RF generating system 120 generates and outputs an RF voltage to one of the upper electrode 104 and the lower electrode (e.g., the baseplate 110 of the substrate support 106). The other one of the upper electrode 104 and the baseplate 110 may be DC grounded, AC grounded or floating. For example only, the RF generating system 120 may include an RF voltage generator 122 that generates the RF voltage that is fed by a matching and distribution network 124 to the upper electrode 104 or the baseplate 110. In other examples, the plasma may be generated inductively or remotely. Although, as shown for example purposes, the RF generating system 120 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

A gas delivery system 130 includes one or more gas sources 132-1, 132-2, . . . , and 132-N (collectively gas sources 132), where N is an integer greater than zero. The gas sources supply one or more precursors and mixtures thereof. The gas sources may also supply purge gas. Vaporized precursor may also be used. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. An output of the manifold 140 is fed to the processing chamber 102. For example only, the output of the manifold 140 is fed to the showerhead 109.

A temperature controller 142 may be connected to a plurality of heating elements, such as thermal control elements (TCEs) 144 arranged in the ceramic layer 112. For example, the heating elements 144 may include, but are not limited to, macro heating elements corresponding to respective zones in a multi-zone heating plate and/or an array of micro heating elements disposed across multiple zones of a multi-zone heating plate. The temperature controller 142 may be used to control the plurality of heating elements 144 to control a temperature of the substrate support 106 and the substrate 108. Each of the heating elements 144 according to the principles of the present disclosure includes a first material having a positive TCR and a second material having a negative TCR as described below in more detail.

The temperature controller 142 may communicate with a coolant assembly 146 to control coolant flow through the channels 116. For example, the coolant assembly 146 may include a coolant pump and reservoir. The temperature controller 142 operates the coolant assembly 146 to selectively flow the coolant through the channels 116 to cool the substrate support 106.

A valve 150 and pump 152 may be used to evacuate reactants from the processing chamber 102. A system controller 160 may be used to control components of the substrate processing system 100. A robot 170 may be used to deliver substrates onto, and remove substrates from, the substrate support 106. For example, the robot 170 may transfer substrates between the substrate support 106 and a load lock 172. Although shown as separate controllers, the temperature controller 142 may be implemented within the system controller 160. In some examples, a protective seal 176 may be provided around a perimeter of the bond layer 114 between the ceramic layer 112 and the baseplate 110.

The ceramic layer 112 includes sidewalls that are modified according to the principles of the present disclosure. For example, sidewalls of the ceramic layer 112 are coated with a protective layer, polished, and/or acid-etched as described below in more detail.

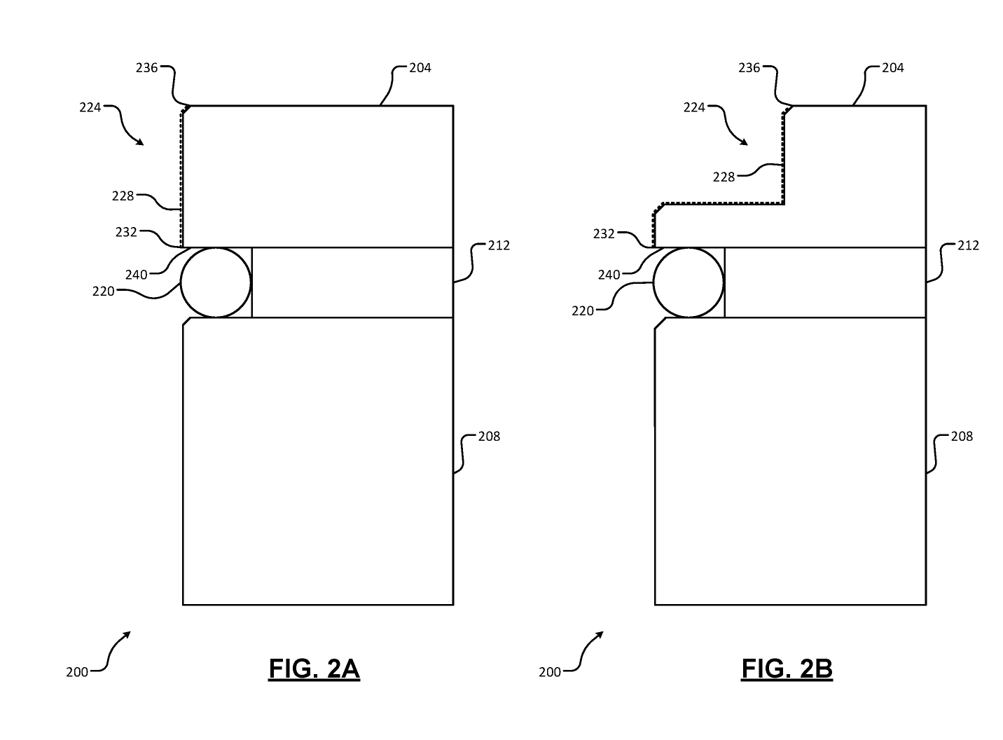

Referring now to FIGS. 2A, 2B, and 2C, respective portions of example substrate supports 200 are shown. In FIG. 2A, the substrate support 200 is shown with a non-stepped ceramic layer configuration. In FIG. 2B, the substrate support 200 is shown with a stepped ceramic layer configuration. The substrate support 200 includes a ceramic layer 204 arranged on a baseplate 208. In some examples, the ceramic layer 204 may correspond to a ceramic plate configured as a heating layer (e.g., a ceramic plate including embedded heating elements). The ceramic layer 204 comprises a first (e.g., primary) material such as aluminum oxide grains, aluminum nitride, etc. with or without metal oxide binders. A bond layer 212 is provided between the ceramic layer 204 and the baseplate 208. A protective seal 220 may be provided around a perimeter of the bond layer 212 between the ceramic layer 204 and the baseplate 208. An edge ring, which is omitted in FIGS. 2A and 2B for simplicity, may be arranged around an outer edge of the ceramic layer 204 and the baseplate 208 as shown in FIG. 1.

While sidewalls 224 of the ceramic layer 204 may be partially protected by an edge ring and/or a substrate overlapping a gap between the edge ring and the ceramic layer 204, the sidewalls 224 are nonetheless exposed to plasma during processing. Accordingly, the sidewalls 224 of the ceramic layer 204 are coated with a protective layer or coating 228 comprising a second material. The protective layer 228 provides a barrier between reactive species within the processing chamber and the sidewalls 224 of the ceramic layer 204.

In one example, the protective layer 228 may comprise a non-alumina based material, such as an yttrium oxide spraycoat (e.g., a plasma spraycoat), although other suitable materials having greater wear resistance to plasma may be used. In other examples, the protective layer 228 comprises a sacrificial material that protects the ceramic layer 204 but is susceptible to wear caused by exposure to plasma. The sacrificial material would be replaced (e.g., reapplied via spraycoat techniques) periodically to maintain the protective layer 228 over the sidewalls 224 of the ceramic layer 204. For example, the sacrificial material may be replaced after a predetermined amount of time and/or a predetermined number of process steps, hours of use, etc.

The protective layer 228 is applied to the sidewalls 224 around an entire circumference of the ceramic layer 204 at a desired thickness. The thickness of the protective layer 228 is selected such that the sidewalls 224 are entirely covered while reducing the likelihood that the protective layer 228 will delaminate from the ceramic layer 204. In one example, the thickness of the protective layer 228 is between 5 and 10 mils (i.e., 0.005″ and 0.010″) thick.

The protective layer 228 extends between a bottom edge 232 of the sidewall 224 to a top edge 236 of the sidewall 224. In one example, the protective layer 228 does not extend completely to the top edge 236 and instead terminates a nominal distance (e.g., 1 mil, or 0.001″) from the top edge 236 as shown. Accordingly, contact between the protective layer 228 at the top edge 236 and a substrate clamped to an upper surface of the ceramic layer 204 is prevented. Similarly, the protective layer 228 does not extend under the ceramic layer 204 to prevent contact between the protective layer 228 at the bottom edge 232 and the seal 220. In this manner, damage to the protective layer 228 may be avoided. In some examples, however, the protective layer 228 may extend completely to the top edge 236 and/or onto a bottom surface 240 of the ceramic layer 204 as shown in FIG. 2C. The top edge 236 of the sidewall 224 may be chamfered as shown. In some examples, the thickness of the protective layer 228 may taper near the bottom edge 232 and/or the top edge 236. For example only, the protective layer 228 may taper from between 5 and 10 mils thick to 1 mil thick at the top edge 236.

In another example, the sidewalls 224 of the ceramic layer 204 are polished. Polishing reduces the surface area of the sidewalls 224, thereby reducing the amount of material exposed to plasma. For example only, the sidewalls 224 may have an initial surface roughness of 30-60 micro-inches. Conversely, the sidewalls 224 according to the principles of the present disclosure are polished to a surface roughness less than 30 micro-inches. In one example, the sidewalls 224 are polished to a surface roughness of 1-20 micro-inches. In another example, the sidewalls 224 are ultra-polished to a surface roughness of less than 10 micro-inches, less than 3 micro-inches, or less than 1 micro-inch.

The sidewalls 224 may be polished using suitable ceramic polishing systems and methods. In one example, the sidewalls 224 are polished using a polishing substrate (e.g., a brush) and a polishing material (e.g., diamond grit polishing paste).

In still another example, the sidewalls 224 of the ceramic layer 204 are acid-etched. Acid-etching the sidewalls 224 preemptively removes material from the ceramic layer 204 that would otherwise be removed during other plasma processes and result in impurities within the chamber.

For example, the ceramic layer 204 may be formed using an alumina or nitride material and a sintering aid. The sintering aid may comprise materials such as calcium oxide, magnesium oxide, silicon dioxide, etc. Further, the ceramic material may ultimately comprise multiple phases, such as a crystalline, alumina-rich phase and a mixed material glassy phase. Typically, the glassy phase of the ceramic layer 204 has a greater susceptibility to etching and/or sputtering when exposed to plasma than the alumina phase. Acid etching the sidewalls 224 removes an outer portion (e.g., outer microns) of the glassy phase material from the ceramic layer 204. In this manner, glassy phase material associated with sputtering and/or re-deposition is preemptively removed from the ceramic layer 204. Example materials for performing the acid etching of the sidewalls 224 include, but are not limited to, nitric and hydrofluoric acids.

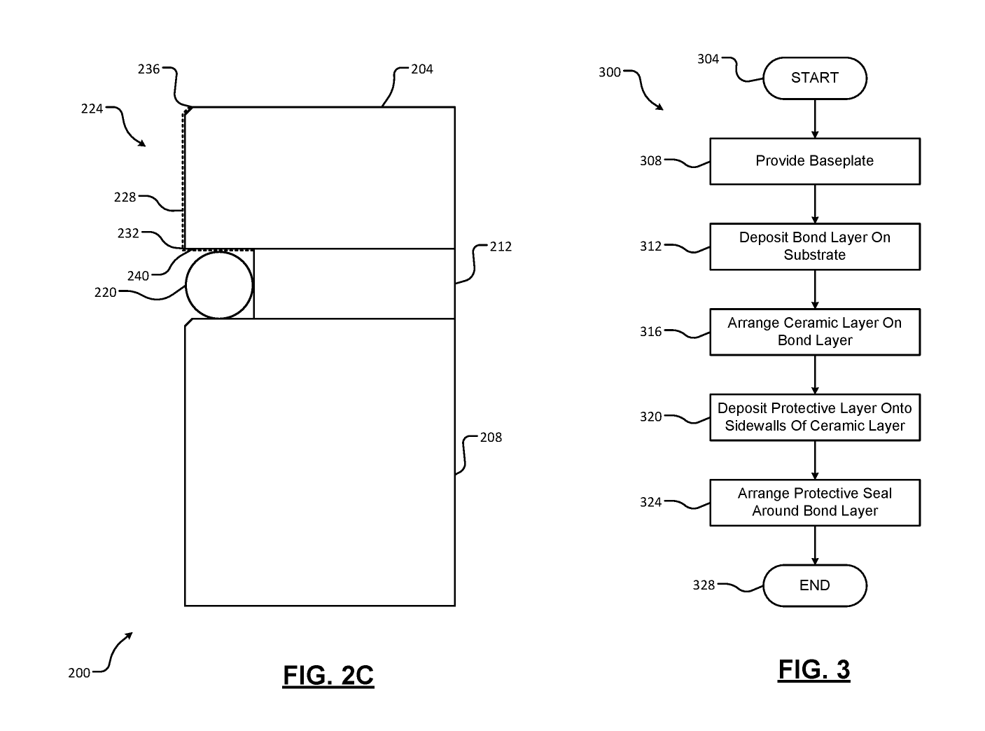

Referring now to FIG. 3, a first example method 300 of forming a substrate support according to the principles of the present disclosure starts at 304. At 308, a baseplate is provided. At 312, a bond layer is deposited on the baseplate. At 316, a ceramic layer is arranged on the bond layer. At 320, a protective layer is deposited on sidewalls of the ceramic layer as described above in FIGS. 2A, 2B, and 2C. For example, the protective layer is spray coated onto the ceramic layer. At 324, a protective seal is arranged around the bond layer. In some examples, the protective seal may be arranged around the bond layer prior to depositing the protective layer at 320. In other examples, the protective layer may be deposited onto the sidewalls of the ceramic layer prior to arranging the ceramic layer on the bond layer. In other words, the protective layer may be applied prior to assembling the substrate support. The method 300 ends at 328.

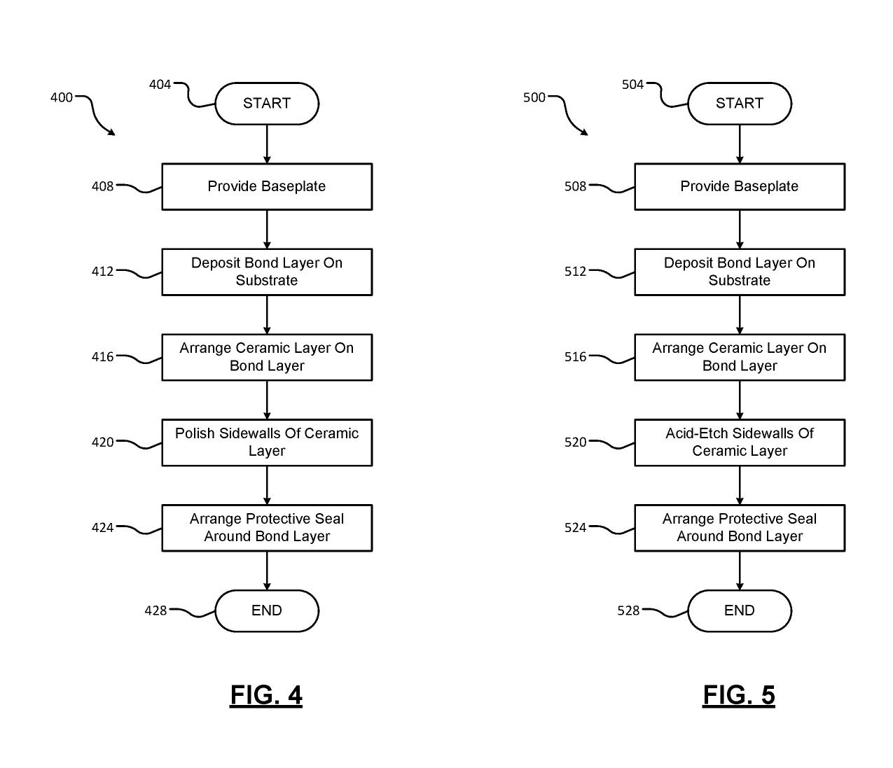

Referring now to FIG. 4, a second example method 400 of forming a substrate support according to the principles of the present disclosure starts at 404. At 408, a baseplate is provided. At 412, a bond layer is deposited on the baseplate. At 416, a ceramic layer is arranged on the bond layer. At 420, sidewalls of the ceramic layer are polished as described above in FIGS. 2A, 2B, and 2C. For example, the sidewalls of the ceramic layer are polished to a surface roughness of less than 30 micro-inches (e.g., using a polishing substrate and a polishing material). At 424, a protective seal is arranged around the bond layer. In some examples, the protective seal may be arranged around the bond layer prior to polishing the sidewalls at 420. In other examples, the sidewalls of the ceramic layer may be polished prior to arranging the ceramic layer on the bond layer. In other words, the polishing may be performed prior to assembling the substrate support. The method 400 ends at 428.

Referring now to FIG. 5, a third example method 500 of forming a substrate support according to the principles of the present disclosure starts at 504. At 508, a baseplate is provided. At 512, a bond layer is deposited on the baseplate. At 516, a ceramic layer is arranged on the bond layer. At 520, sidewalls of the ceramic layer are acid-etched as described above in FIGS. 2A, 2B, and 2C. For example, the sidewalls of the ceramic layer are acid-etched (e.g., using nitic and/or hydrofluoric acids) to remove an outer portion of a glassy phase material from the sidewalls. At 524, a protective seal is arranged around the bond layer. In some examples, the protective seal may be arranged around the bond layer prior to acid-etching the sidewalls at 520. In other examples, the sidewalls of the ceramic layer may be acid-etched prior to arranging the ceramic layer on the bond layer. In other words, the acid-etching may be performed prior to assembling the substrate support. The method 500 ends at 528.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller maybe defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate support for a substrate processing system, the substrate support comprising:
a baseplate;
a ceramic layer arranged on the baseplate, wherein the ceramic layer includes a lower surface, an upper surface configured to support a substrate, and sidewalls around a perimeter of the ceramic layer extending from the lower surface to the upper surface, and wherein the ceramic layer comprises a first material;
a bond layer provided between the baseplate and the ceramic layer; and
a protective layer formed on the sidewalls of the ceramic layer, wherein the protective later comprises a second material different from the first material.

2. The substrate support of claim 1, wherein the second material is a non-alumina based material.

3. The substrate support of claim 1, wherein the second material is an yttrium oxide spraycoat.

4. The substrate support of claim 1, wherein the second material has a greater resistance to plasma than the first material.

5. The substrate support of claim 1, wherein a thickness of the protective layer is between 0.005″ and 0.010″.

6. The substrate support of claim 1, wherein the protective layer extends from a bottom edge of the sidewalls adjacent to the lower surface to a top edge of the sidewalls adjacent to the upper surface.

7. The substrate support of claim 1, wherein the protective layer extends from a bottom edge of the sidewalls adjacent to the lower surface to a predetermined distance from atop edge of the sidewalls adjacent to the upper surface.

8. The substrate support of claim 7, wherein the predetermined distance is at least 0.001″ from the top edge.

9. The substrate support of claim 1, wherein atop edge of the sidewalls adjacent to the upper surface is chamfered.

10. The substrate support of claim 1, wherein a thickness of the protective layer tapers at at least one of a bottom edge of the sidewalls adjacent to the lower surface and a top edge of the sidewalls adjacent to the upper surface.

11. The substrate support of claim 10, wherein the thickness of the protective layer tapers from between 0.005″ and 0.010″ to 0.001″.

12. The substrate of claim 1, further comprising a protective seal arranged around a perimeter of the bond layer between the baseplate and the lower surface of the ceramic layer, wherein the protective seal does not extend onto the lower surface of the ceramic layer.

13. A method for forming a substrate support for a substrate processing system, the method comprising:
providing a baseplate;
depositing a bond layer on the baseplate;
arranging a ceramic layer on the baseplate, wherein the ceramic layer includes a lower surface, an upper surface configured to support a substrate, and sidewalls around a perimeter of the ceramic layer extending from the lower surface to the upper surface, and wherein the ceramic layer comprises a first material; and
at least one of
forming a protective layer on the sidewalls of the ceramic layer, wherein the protective later comprises a second material different from the first material,
polishing the sidewalls of the ceramic layer, and
acid-etching the sidewalls of the ceramic layer.

14. The substrate support of claim 13, wherein the second material is a non-alumina based material.

15. The substrate support of claim 13, wherein forming the protective layer includes applying an yttrium oxide spraycoat on the sidewalls of the ceramic layer.

16. The substrate support of claim 13, wherein the second material has a greater resistance to plasma than the first material.

17. The substrate support of claim 13, wherein polishing the sidewalls of the ceramic layer includes polishing the sidewalls to a surface roughness of less than 30 micro-inches.

18. The substrate support of claim 13, wherein polishing the sidewalls of the ceramic layer includes polishing the sidewalls to a surface roughness of less than 10 micro-inches.

19. The substrate support of claim 13, wherein acid-etching the sidewalls of the ceramic layer includes acid-etching the sidewalls to remove an outer portion of a glassy phase material of the sidewalls.
